(19) United States
(12) Patent Application Publication
(10) Pub. No.: US 2024/0119689 A1
(43) Pub. Date: Apr. 11, 2024

(54) NON-TRANSITORY COMPUTER READABLE MEDIUM

(71) Applicant: TOYOTA JIDOSHA KABUSHIKI KAISHA, Toyota-shi (JP)

(72) Inventors: Kotaro OKABE, Ichikawa-shi (JP); Shuhei YAMAMOTO, Chofu-shi (JP)

(73) Assignee: TOYOTA JIDOSHA KABUSHIKI KAISHA, Toyota-shi (JP)

(21) Appl. No.: 18/473,274

(22) Filed: Sep. 25, 2023

(30) Foreign Application Priority Data
Oct. 7, 2022 (JP) 2022-162768

(51) Int. Cl. G06T 19/20; G06T 19/00

(52) U.S. Cl. CPC G06T 19/20; G06T 19/006; G06T 2219/2004

(57) ABSTRACT

A program is configured to cause a computer to execute operations, the operations comprising displaying, on a display, an image of an equipment layout in a virtual space corresponding to an interior space of a vehicle, upon accepting a candidate selection operation to select equipment to be used for providing a service in the interior space of the vehicle as candidate equipment and a location in the interior space of the vehicle as a candidate location, determining, with reference to vehicle data defining a specification of the vehicle, whether to allow installation of the candidate equipment at the candidate location, and upon determining to allow installation of the candidate equipment at the candidate location, updating the equipment layout by arranging a model corresponding to the candidate equipment at a location corresponding to the candidate location in the virtual space.

### CROSS-REFERENCE TO RELATED APPLICATION

This application claims priority to Japanese Patent Application No. 2022-162768 filed on Oct. 7, 2022, the entire contents of which are incorporated herein by reference.

### TECHNICAL FIELD

The present disclosure relates to a program.

### BACKGROUND

Patent Literature (PTL) 1 discloses an apparatus that draws furniture modeling data in a VR stereoscopic image illustrating the shape of a room. The term “VR” is an abbreviation of virtual reality.

### CITATION LIST

### Patent Literature

PTL 1: JP 2022-068596 A

### SUMMARY

When considering the interior of a vehicle, an equipment layout may be displayed virtually. However, if it is allowed to freely arrange equipment without taking into account the specifications of the vehicle, an interior that cannot be adopted in reality could possibly be considered or determined.

It would be helpful to facilitate considering interiors of vehicles, taking into account the specifications of the vehicles.

A program according to the present disclosure is configured to cause a computer to execute operations, the operations including:
displaying, on a display, an image of an equipment layout in a virtual space corresponding to an interior space of a vehicle;
upon accepting a candidate selection operation to select equipment to be used for providing a service in the interior space as candidate equipment and a location in the interior space as a candidate location, determining, with reference to vehicle data defining a specification of the vehicle, whether to allow installation of the candidate equipment at the candidate location; and
upon determining to allow installation of the candidate equipment at the candidate location, updating the equipment layout by arranging a model corresponding to the candidate equipment at a location corresponding to the candidate location in the virtual space.

According to the present disclosure, it is possible to facilitate considering interiors of vehicles, taking into account the specifications of the vehicles.

### BRIEF DESCRIPTION OF THE DRAWINGS

In the accompanying drawings:

FIG. 1 is a block diagram illustrating a configuration of a terminal apparatus according to an embodiment of the present disclosure and databases to be used by the terminal apparatus;

FIG. 2 is a flowchart illustrating operations of the terminal apparatus according to the embodiment of the present disclosure;

FIG. 3 is a diagram illustrating an example of a screen output by the terminal apparatus according to the embodiment of the present disclosure;

FIG. 4 is a diagram illustrating an example of another screen output by the terminal apparatus according to the embodiment of the present disclosure;

FIG. 5 is a diagram illustrating an example of an alert output by the terminal apparatus according to the embodiment of the present disclosure; and

FIG. 6 is a flowchart illustrating a variation of the operations of the terminal apparatus according to the embodiment of the present disclosure.

### DETAILED DESCRIPTION

An embodiment of the present disclosure will be described below, with reference to the drawings.

In the drawings, the same or corresponding portions are denoted by the same reference numerals. In the descriptions of the present embodiment, detailed descriptions of the same or corresponding portions are omitted or simplified, as appropriate.

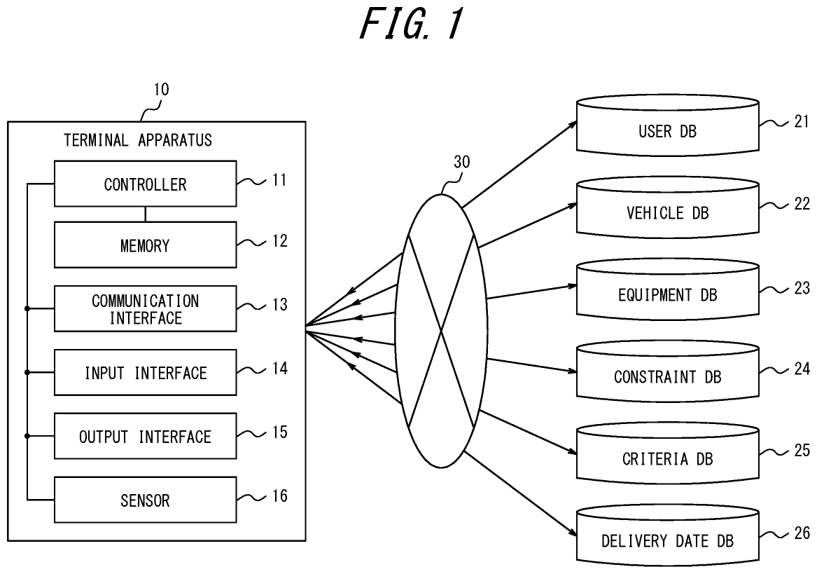

An outline of the present embodiment will be described with reference to FIG. 1.

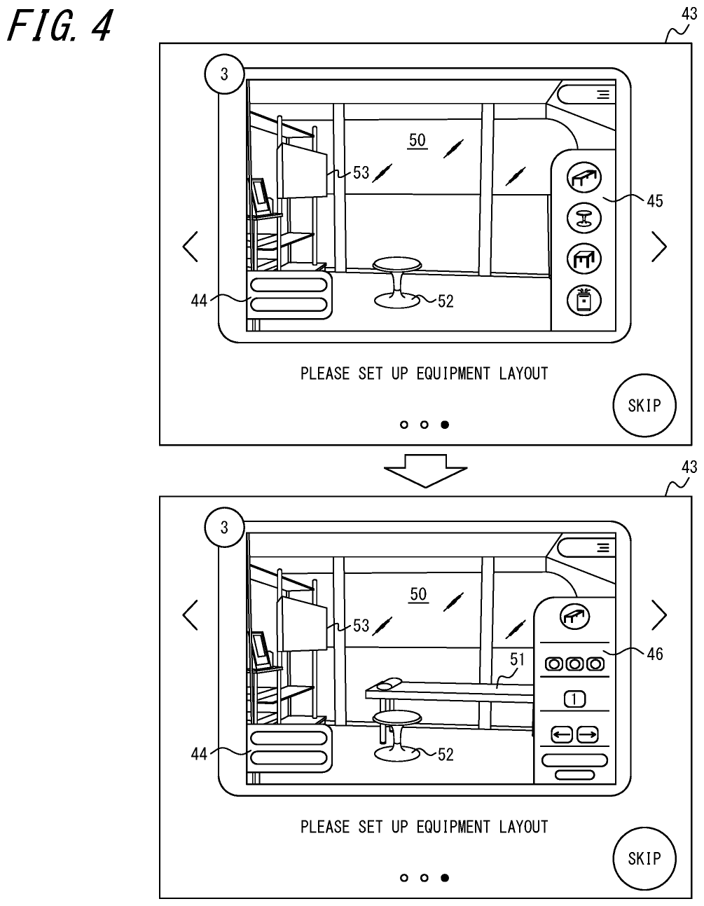

A terminal apparatus 10 displays, on a display, an image of an equipment layout in a virtual space 50 corresponding to an interior space of a vehicle, as illustrated in FIG. 4. Upon accepting a candidate selection operation, the terminal apparatus 10 determines, with reference to vehicle data D2, whether to allow installation of a candidate equipment at a candidate location. The candidate selection operation is an operation to select equipment to be used for providing a service in the interior space of the vehicle as candidate equipment and a location in the interior space of the vehicle as a candidate location. The vehicle data D2 is data defining the specifications of the vehicle. Upon determining to allow installation of the candidate equipment at the candidate location, the terminal apparatus 10 updates the equipment layout by arranging a model corresponding to the candidate equipment at a location corresponding to the candidate location in the virtual space 50.

According to the present embodiment, the equipment layout can be displayed virtually when the interior of the vehicle is considered. Moreover, when the candidate equipment and the candidate location are selected, whether to allow installation of the candidate equipment at the candidate location is determined with reference to the data defining the specifications of the vehicle, thus reducing the possibility that interiors that cannot actually be adopted are considered or determined. Therefore, the present embodiment facilitates considering interiors of vehicles, taking into account the specifications of the vehicles.

The vehicle is, for example, any type of automobile such as a gasoline vehicle, a diesel vehicle, a hydrogen vehicle, an HEV, a PHEV, a BEV, or an FCEV. The term “HEV” is an abbreviation of hybrid electric vehicle. The term “PHEV” is an abbreviation of plug-in hybrid electric vehicle. The term “BEV” is an abbreviation of battery electric vehicle. The term “FCEV” is an abbreviation of fuel cell electric vehicle. The vehicle may be an AV, or may be driven by a driver, or the driving may be automated at any level. The term “AV” is an abbreviation of autonomous vehicle. The automation level is, for example, any one of Level 1 to Level 5 according to the level classification defined by SAE. The name “SAE” is an abbreviation of Society of Automotive Engineers. The vehicle may be a MaaS-dedicated vehicle. The term “MaaS” is an abbreviation of Mobility as a Service.

A configuration of the terminal apparatus 10 according to the present embodiment will be described with reference to FIG. 1.

The terminal apparatus 10 is installed in a dealership, such as a car dealership, or held by a user who is a customer or employee of the dealership and used by the user. The terminal apparatus 10 is, for example, a mobile device such as a mobile phone, a smartphone, or a tablet, or a PC. The term “PC” is an abbreviation of personal computer. An application corresponding to a program according to the present embodiment is installed in the terminal apparatus 10.

The terminal apparatus 10 includes a controller 11, a memory 12, a communication interface 13, an input interface 14, an output interface 15, and a sensor 16.

The controller 11 includes at least one processor, at least one programmable circuit, at least one dedicated circuit, or any combination thereof. The processor is a general purpose processor such as a CPU or a GPU, or a dedicated processor that is dedicated to specific processing. The term “CPU” is an abbreviation of central processing unit. The term “GPU” is an abbreviation of graphics processing unit. The programmable circuit is, for example, an FPGA. The term “FPGA” is an abbreviation of field-programmable gate array. The dedicated circuit is, for example, an ASIC. The term “ASIC” is an abbreviation of application specific integrated circuit. The controller 11 executes processes related to the operations of the terminal apparatus 10 while controlling the components of the terminal apparatus 10.

The memory 12 includes at least one semiconductor memory, at least one magnetic memory, at least one optical memory, or any combination thereof. The semiconductor memory is, for example, RAM, ROM, or flash memory. The term “RAM” is an abbreviation of random access memory. The term “ROM” is an abbreviation of read only memory. The RAM is, for example, SRAM or DRAM. The term “SRAM” is an abbreviation of static random access memory. The term “DRAM” is an abbreviation of dynamic random access memory. The ROM is, for example, EEPROM. The term “EEPROM” is an abbreviation of electrically erasable programmable read only memory. The flash memory is, for example, SSD. The term “SSD” is an abbreviation of solid-state drive. The magnetic memory is, for example, HDD. The term “HDD” is an abbreviation of hard disk drive. The memory 12 functions as, for example, a main memory, an auxiliary memory, or a cache memory. The memory 12 stores data to be used for operations of the terminal apparatus 10 and data obtained by the operations of the terminal apparatus 10.

The communication interface 13 includes at least one interface for communication. The interface for communication is, for example, an interface compatible with a wired LAN communication standard such as Ethernet® (Ethernet is a registered trademark in Japan, other countries, or both), a wireless LAN communication standard such as IEEE802.11, or a mobile communication standard such as LTE, the 4G standard, or the 5G standard. The term “LAN” is an abbreviation of local area network. The name “IEEE” is an abbreviation of Institute of Electrical and Electronics Engineers. The term “LTE” is an abbreviation of Long Term Evolution. The term “4G” is an abbreviation of 4th generation. The term “5G” is an abbreviation of 5th generation. The communication interface 13 receives data to be used for the operations of the terminal apparatus 10, and transmits data obtained by the operations of the terminal apparatus 10.

The input interface 14 includes at least one interface for input. The interface for input is, for example, a physical key, a capacitive key, a pointing device, a touch screen integrally provided with a display, a camera, a LiDAR sensor, or a microphone. “LiDAR” is an abbreviation of light detection and ranging. The input interface 14 accepts an operation for inputting data to be used for the operations of the terminal apparatus 10. The input interface 14 may be connected to the terminal apparatus 10 as an external input device, instead of being included in the terminal apparatus 10. As an interface for connection, an interface compliant with a standard such as USB, HDMI® (HDMI is a registered trademark in Japan, other countries, or both), or Bluetooth® (Bluetooth is a registered trademark in Japan, other countries, or both) can be used. The term “USB” is an abbreviation of Universal Serial Bus. The term “HDMI®” is an abbreviation of High-Definition Multimedia Interface.

The output interface 15 includes at least one interface for output. The interface for output is, for example, a display or a speaker. The display is, for example, an LCD or an organic EL display. The term “LCD” is an abbreviation of liquid crystal display. The term “EL” is an abbreviation of electro luminescent. The output interface 15 outputs data obtained by the operations of the terminal apparatus 10. The output interface 15 may be connected to the terminal apparatus 10 as an external output device, instead of being included in the terminal apparatus 10. As an interface for connection, an interface compliant with a standard such as USB, HDMI®, or Bluetooth® can be used.

The sensor 16 includes at least one sensor for VR or at least one sensor for AR. The term “AR” is an abbreviation of augmented reality. The sensor for VR is, for example, an accelerometer, an angular rate sensor, or a magnetometer. The sensor for AR is also, for example, an accelerometer, an angular rate sensor, or a magnetometer. The sensor 16 detects changes in the position or orientation of the terminal apparatus 10, and in particular, changes in the position or orientation of the display as the output interface 15.

The functions of the terminal apparatus 10 are realized by execution of a program according to the present embodiment by a processor serving as the controller 11. That is, the functions of the terminal apparatus 10 are realized by software. The program causes a computer to execute the operations of the terminal apparatus 10, thereby causing the computer to function as the terminal apparatus 10. That is, the computer executes the operations of the terminal apparatus 10 in accordance with the program to thereby function as the terminal apparatus 10.

The program can be stored on a non-transitory computer readable medium. The non-transitory computer readable medium is, for example, flash memory, a magnetic recording device, an optical disc, a magneto-optical recording medium, or ROM. The program is distributed, for example, by selling, transferring, or lending a portable medium such as an SD card, a DVD, or a CD-ROM on which the program is stored. The term “SD” is an abbreviation of Secure Digital. The term “DVD” is an abbreviation of digital versatile disc. The term “CD-ROM” is an abbreviation of compact disc read only memory. The program may be distributed by storing the program in a storage of a server and transferring the program from the server to another computer. The program may be provided as a program product.

For example, the computer temporarily stores, in a main memory, a program stored in a portable medium or a program transferred from a server. Then, the computer reads the program stored in the main memory using a processor, and executes processes in accordance with the read program using the processor. The computer may read a program directly from the portable medium, and execute processes in accordance with the program. The computer may, each time a program is transferred from the server to the computer, sequentially execute processes in accordance with the received program. Instead of transferring a program from the server to the computer, processes may be executed by a so-called ASP type service that realizes functions only by execution instructions and result acquisitions. The term “ASP” is an abbreviation of application service provider. Programs encompass information that is to be used for processing by an electronic computer and is thus equivalent to a program. For example, data that is not a direct command to a computer but has a property that regulates processing of the computer is “equivalent to a program” in this context.

Some or all of the functions of the terminal apparatus 10 may be realized by a programmable circuit or a dedicated circuit serving as the controller 11. That is, some or all of the functions of the terminal apparatus 10 may be realized by hardware.

Databases used by the terminal apparatus 10 will be described with reference to FIG. 1.

The terminal apparatus 10 can access a user database 21, a vehicle database 22, an equipment database 23, a constraint database 24, a criteria database 25, and a delivery date database 26 via a network 30.

The user database 21 is a database that stores user data D1. The user data D1 includes data indicating users' IDs. The term “ID” is an abbreviation of identifier. The user data D1 may include data indicating the users' passwords.

The vehicle database 22 is a database that stores vehicle data D2. The vehicle data D2 includes data indicating the shapes and sizes of interior spaces of vehicles, for each vehicle type. The vehicle data D2 may include data defining upper limits of loads of the vehicles, for each vehicle type. Alternatively, the vehicle data D2 may include data defining upper limits of power consumption of the vehicles, for each vehicle type.

The equipment database 23 is a database that stores equipment data D3. The equipment data D3 includes data indicating the shape and size of equipment, for each equipment type. The equipment data D3 may include data indicating the weight of equipment, for each equipment type. For equipment that consumes power, the equipment data D3 may include data indicating the power consumption of the equipment.

The constraint database 24 is a database that stores constraint data D4. The constraint data D4 includes data defining constraints or prohibitions during traveling of the vehicles, for each vehicle type. The constraints include, for example, constraints prescribed by law. The prohibitions also include, for example, prohibitions prescribed by law.

The criteria database 25 is a database that stores criteria data D5. The criteria data D5 includes data defining the security standards of the vehicles, for each vehicle type.

The delivery date database 26 is a database that stores delivery date data D6. The delivery date data D6 includes data necessary to predict delivery dates of the vehicles, for each vehicle type.

The network 30 includes the Internet, at least one WAN, at least one MAN, or any combination thereof. The term “WAN” is an abbreviation of wide area network. The term “MAN” is an abbreviation of metropolitan area network. The network 30 may include at least one wireless network, at least one optical network, or any combination thereof. The wireless network is, for example, an ad hoc network, a cellular network, a wireless LAN, a satellite communication network, or a terrestrial microwave network.

The user database 21, the vehicle database 22, the equipment database 23, the constraint database 24, the criteria database 25, and the delivery date database 26 are built on an external storage such as a cloud storage in the present embodiment, but may be built on the memory 12 of the terminal apparatus 10. In such a variation, the terminal apparatus 10 can access the user database 21, the vehicle database 22, the equipment database 23, the constraint database 24, the criteria database 25, and the delivery date database 26 without passing through the network 30.

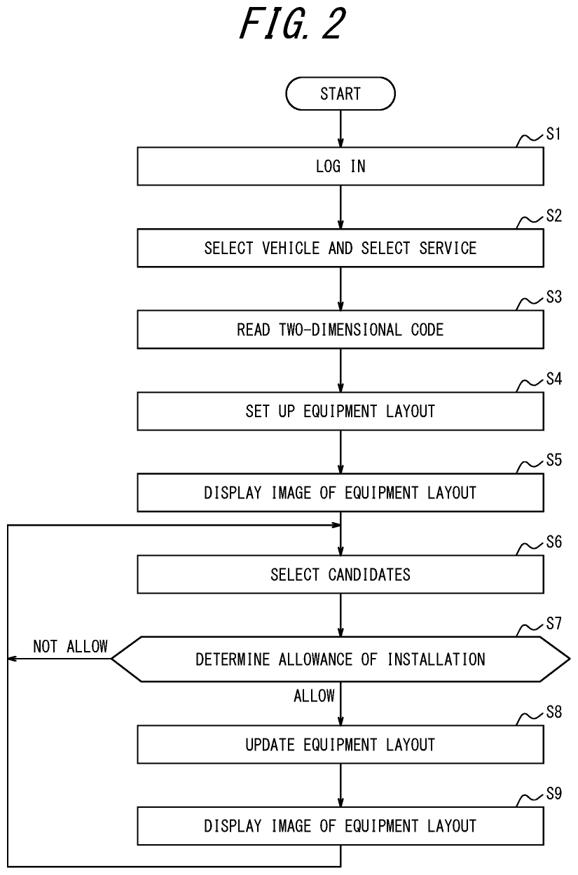

Operations of the terminal apparatus 10 according to the present embodiment will be described with reference to FIG. 2. These operations correspond to an equipment layout image display method according to the present embodiment.

In step S1, the controller 11 of the terminal apparatus 10 accepts a login operation via the input interface 14. The login operation is an operation to enter a user's ID. The login operation may include an operation to enter the user's password. The controller 11 may acquire user data D1 by searching the user database 21 via the communication interface 13 using the entered ID as a key. The controller 11 may authenticate the user by checking the entered password against a password of a user indicated by the acquired user data D1. When the authentication fails, the flow illustrated in FIG. 2 may be terminated.

In step S2, the controller 11 of the terminal apparatus 10 accepts a vehicle selection operation and a service selection operation via the input interface 14. The vehicle selection operation is an operation to select a vehicle type. The service selection operation is an operation to select a service type.

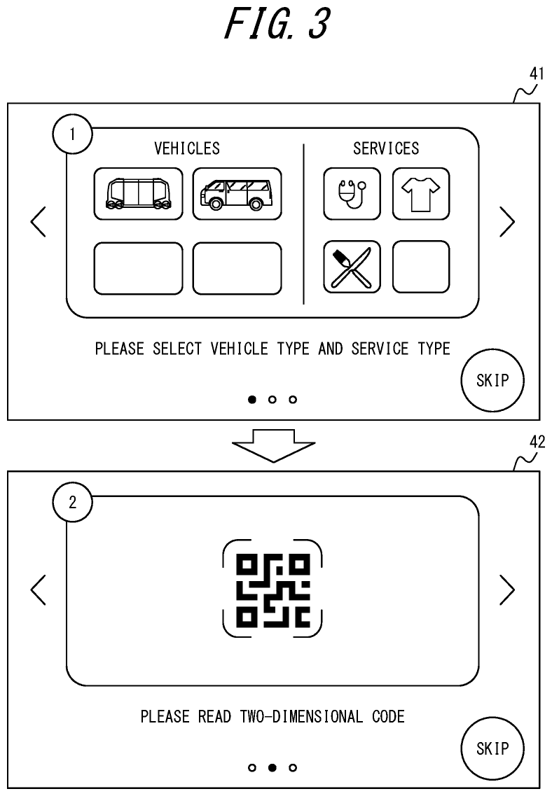

Specifically, the controller 11 of the terminal apparatus 10 displays, as illustrated on the upper side of FIG. 3, a selection screen 41 for the vehicle selection operation and the service selection operation on the display as the output interface 15. The controller 11 accepts, as the vehicle selection operation, an operation to select a vehicle type from among choices, such as MaaS-only vehicles and vans, on the selection screen 41. The controller 11 accepts, as the service selection operation, an operation to select a service type from among choices, such as medical care, apparel, food and beverage, sightseeing, and luggage lockers, on the selection screen 41.

In step S3, the controller 11 of the terminal apparatus 10 accepts a two-dimensional code reading operation via the input interface 14. The two-dimensional code reading operation is an operation to read a two-dimensional code disposed at a reference location for creating a VR or AR space.

Specifically, the controller 11 of the terminal apparatus 10 displays, as illustrated on the lower side of FIG. 3, a read screen 42 for the two-dimensional code reading operation on the display as the output interface 15. The controller 11 prompts the user to capture the two-dimensional code with a camera, as the input interface 14, while displaying a preview image acquired by the camera on the read screen 42. The two-dimensional code is printed, for example, on a piece of paper placed on a stand about one meter high, or on a sticker attached to a similar stand.

In step S4, the controller 11 of the terminal apparatus 10 acquires vehicle data D2 by searching the vehicle database 22 via the communication interface 13 using the vehicle type selected in step S2 as a key. The controller 11 creates, with reference to the acquired vehicle data D2, a virtual space 50 corresponding to an interior space of a vehicle. The controller 11 acquires equipment data D3 by searching the equipment database 23 via the communication interface 13 using, as keys, equipment types included in a different set of equipment depending on the service type selected in step S2. The controller 11 sets up an equipment layout in the virtual space 50 by arranging in the virtual space 50, with reference to the acquired equipment data D3, a set of models corresponding to the different set of equipment depending on the service type selected in step S2.

The controller 11 of the terminal apparatus 10 may further acquire constraint data D4 by searching the constraint database 24 via the communication interface 13 using the vehicle type selected in step S2 as a key. The controller 11 of the terminal apparatus 10 may further acquire criteria data D5 by searching the criteria database 25 via the communication interface 13 using the vehicle type selected in step S2 as a key. The controller 11 of the terminal apparatus 10 may further acquire delivery date data D6 by searching the delivery date database 26 via the communication interface 13 using the vehicle type selected in step S2 as a key.

In step S5, the controller 11 of the terminal apparatus 10 displays an image of the equipment layout set in step S4 on the display as the output interface 15.

Specifically, the controller 11 of the terminal apparatus 10 displays, as illustrated on the upper side of FIG. 4, an equipment layout screen 43 including the image of the equipment layout in the virtual space 50 on the display as the output interface 15. For example, assuming that in step S2, a MaaS-only vehicle is selected as a vehicle type, and medical care is selected as a service type. Assuming that a set of equipment including a chair, a monitor, and the like is preset as a package for medical care. In step S4, the controller 11 acquires, as vehicle data D2, data indicating the shape and size of an interior space of the MaaS-only vehicle. The controller 11 creates a VR space or AR space as a virtual space 50 with a shape and size corresponding to the shape and size of the interior space of the MaaS-only vehicle indicated by the vehicle data D2, respectively. The controller 11 acquires, as equipment data D3, data indicating the shape and size of the chair and data indicating the shape and size of the monitor. The controller 11 creates, as a chair model 52, a three-dimensional model with a shape and size corresponding to the shape and size of the chair indicated by the equipment data D3, respectively. The controller 11 creates, as a monitor model 53, a three-dimensional model with a shape and size corresponding to the shape and size of the monitor indicated by the equipment data D3, respectively. The controller 11 sets up an equipment layout by arranging the chair model 52 and the monitor model 53 in the virtual space 50. The locations at which the chair model 52 and the monitor model 53 are arranged may be predetermined or may be set dynamically.

The controller 11 of the terminal apparatus 10 may adjust a display area or display orientation of the equipment layout in the virtual space 50, according to a change in the position or orientation of the display as the output interface 15, which is detected by the sensor 16. For example, in step S4, the controller 11 may create a VR or AR space as the virtual space 50 based on the location of the two-dimensional code read in step S3. Each time the user moves the terminal apparatus 10 or display, the controller 11 may change the appearance of the image of the equipment layout to match the movement.

In step S6, the controller 11 of the terminal apparatus 10 accepts an candidate selection operation via the input interface 14. The candidate selection operation is an operation to select equipment to be used for providing a service in the interior space of the vehicle as candidate equipment and a location in the interior space of the vehicle as a candidate location.

Specifically, the controller 11 of the terminal apparatus 10 displays, as illustrated on the upper side of FIG. 4, buttons 44 including a button for starting the candidate selection operation and an equipment list 45 for performing the candidate selection operation on the equipment layout screen 43. The controller 11 accepts, as the candidate selection operation, an operation to select an equipment type from among choices such as examination tables, chairs, tables, and air cleaners included in the equipment list 45, as well as to select a location in the virtual space 50, on the equipment layout screen 43.

In step S7, the controller 11 of the terminal apparatus 10 determines, with reference to the vehicle data D2 acquired in step S4, whether to allow installation of the candidate equipment selected in step S6 at the candidate location selected in step S6.

Specifically, the controller 11 of the terminal apparatus 10 acquires equipment data D3 by searching the equipment database 23 via the communication interface 13 using the type of the candidate equipment selected in step S6 as a key. The controller 11 determines whether it is physically possible to install the candidate equipment at the candidate location by comparing the shape and size of the candidate equipment indicated by the acquired equipment data D3 with a shape and size near the candidate location in the interior space of the vehicle indicated by the vehicle data D2 acquired in step S4. The controller 11 determines to allow installation of the candidate equipment at the candidate location in a case in which installation of the candidate equipment at the candidate location is physically feasible. The controller 11 determines not to allow installation of the candidate equipment at the candidate location in a case in which installation of the candidate equipment at the candidate location is physically impossible.

Instead of or in addition to whether installation of the candidate equipment at the candidate location is physically possible, whether to allow installation of the candidate equipment at the candidate location may be determined depending on, if the candidate equipment is installed at the candidate location, whether a load of the vehicle exceeds an upper limit. In such a variation, the controller 11 of the terminal apparatus 10 identifies, with reference to the vehicle data D2 acquired in step S4, an upper limit of a load of the vehicle. The controller 11 identifies, with reference to the equipment data D3 acquired in step S4, the weight of equipment corresponding to models that have already been arranged in the virtual space 50. The controller 11 identifies, with reference to newly acquired equipment data D3, the weight of the candidate equipment. The controller 11 determines to allow installation of the candidate equipment at the candidate location in a case in which the sum of weight of the candidate equipment and the equipment corresponding to the models having already been arranged in the virtual space 50 does not exceed the upper limit. The controller 11 determines not to allow installation of the candidate equipment at the candidate location in a case in which the sum of weight of the candidate equipment and the equipment corresponding to the models having already been arranged in the virtual space 50 exceeds the upper limit.

Instead of or in addition to whether installation of the candidate equipment at the candidate location is physically possible, whether to allow installation of the candidate equipment at the candidate location may be determined depending on, if the candidate equipment is installed at the candidate location, whether the power consumption of the vehicle exceeds an upper limit. In such a variation, the controller 11 of the terminal apparatus 10 identifies, with reference to the vehicle data D2 acquired in step S4, an upper limit of power consumption of the vehicle. The controller 11 identifies, with reference to the equipment data D3 acquired in step S4, the power consumption of equipment corresponding to models that have already been arranged in the virtual space 50. The controller 11 identifies, with reference to newly acquired equipment data D3, the power consumption of the candidate equipment. The controller 11 determines to allow installation of the candidate equipment at the candidate location in a case in which the sum of power consumption of the candidate equipment and the equipment corresponding to the models having already been arranged in the virtual space 50 does not exceed the upper limit. The controller 11 determines not to allow installation of the candidate equipment at the candidate location in a case in which the sum of power consumption of the candidate equipment and the equipment corresponding to the models having already been arranged in the virtual space 50 exceeds the upper limit. An auxiliary battery may be selected as the candidate equipment, and the upper limit may be increased according to the output of the auxiliary battery. The electric cost of the vehicle may be displayed.

The controller 11 of the terminal apparatus 10 may determine whether to allow installation of the candidate equipment at the candidate location with reference not only to the vehicle data D2, but also to the constraint data D4, the criteria data D5, the delivery date data D6, or any combination of these data acquired in step S4.

When it is determined in step S7 to allow installation of the candidate equipment at the candidate location, the process in step S8 is performed. When it is determined in step S7 not to allow installation of the candidate equipment at the candidate location, the process in step S6 is performed again.

In step S8, the controller 11 of the terminal apparatus 10 updates the equipment layout in the virtual space 50 by arranging, with reference to the equipment data D3 acquired in step S7, a model corresponding to the candidate equipment selected in step S6 at a location, in the virtual space 50, corresponding to the candidate location selected in step S6.

In step S9, the controller 11 of the terminal apparatus 10 displays an image of the equipment layout updated in step S8 on the display as the output interface 15.

Specifically, as illustrated on the lower side of FIG. 4, the controller 11 of the terminal apparatus 10 continues to display, on the display as the output interface 15, the equipment layout screen 43 including the image of the equipment layout in the virtual space 50. For example, assuming that in step S6, an examination table is selected as candidate equipment, and a location adjacent to a chair is selected as a candidate location. In step S7, the controller 11 acquires data indicating the shape and size of the examination table as equipment data D3. Assuming that it is determined to allow installation of the candidate equipment at the candidate location, in step S8, the controller 11 creates, as an examination table model 51, a three-dimensional model with a shape and size corresponding to the shape and size of the examination table indicated by the equipment data D3. The controller 11 updates the equipment layout by arranging the examination table model 51 at a location, in the virtual space 50, adjacent to the chair model 52.

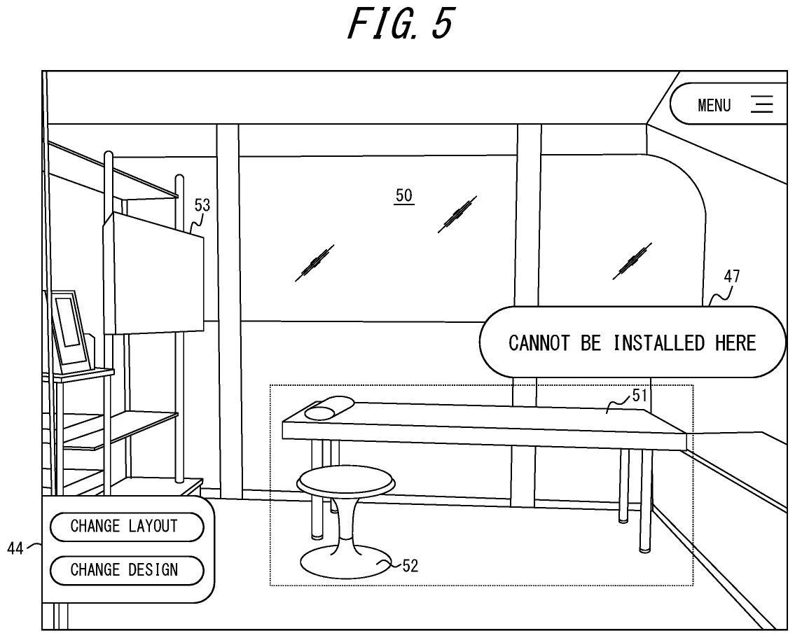

The controller 11 of the terminal apparatus 10 may display, as illustrated on the lower side of FIG. 4, a settings panel 46 on the equipment layout screen 43 to change settings such as the color, product type, or orientation of a model, such as the examination table model 51, arranged in the virtual space 50. Each time the controller 11 updates the equipment layout, the price of the vehicle, the delivery date of the vehicle, or both in the case of applying the updated equipment layout may be displayed on the equipment layout screen 43. In a case in which it is determined in step S7 not to allow installation of the candidate equipment at the candidate location, as illustrated in FIG. 5, the controller 11 may display an alert 47, such as “Cannot be installed here” on the equipment layout screen 43.

After step S9, the process in step S6 is executed again. When a certain condition is met, such as an end of the application, the flow illustrated in FIG. 2 may be terminated.

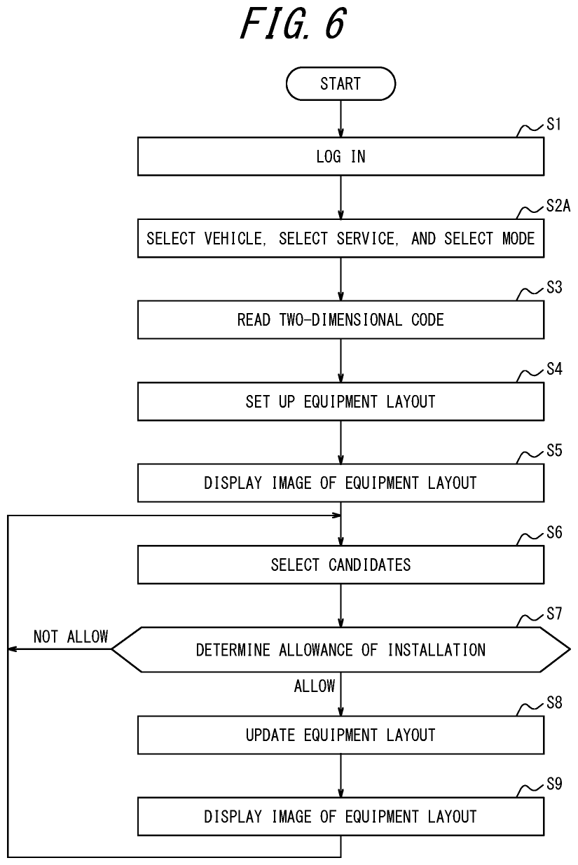

A variation of the operations of the terminal apparatus 10 according to the present embodiment will be described with reference to FIG. 6.

The process in step S1 is the same as the process in step S1 of FIG. 2, and thus a description thereof is omitted.

In step S2A, the controller 11 of the terminal apparatus 10 accepts, via the input interface 14, a vehicle selection operation, a service selection operation, and a mode selection operation. The mode selection operation is an operation to select a mode from among a plurality of modes including a first mode of providing a service while the vehicle is moving and a second mode of providing the service while the vehicle is stopped. For example, the controller 11 accepts, as the mode selection operation, an operation to select a mode from among choices of the first mode, the second mode, and the like on the selection screen 41.

The processes in steps S3 to S5 are the same as the processes in steps S3 to S5 of FIG. 2, respectively, and thus descriptions thereof are omitted. However, in step S4, the controller 11 of the terminal apparatus 10 may acquire equipment data D3 by searching the equipment database 23 via the communication interface 13 using, as a key, types of equipment included in a different set of equipment depending on a combination of the service type and the mode selected in step S2A. The controller 11 may set up an equipment layout in the virtual space 50, by arranging, in the virtual space 50 with reference to the acquired equipment data D3, a set of models corresponding to the different set of equipment depending on the combination of the service type and the mode selected in step S2A. For example, assuming that a chair cannot be fixed to a floor, the chair is not excluded from a medical package when the second mode is selected in step S2A, but the chair may be excluded from the medical package when the first mode is selected in step S2A.

The process of step S6 is similar to the process of step S6 in FIG. 2, except that the candidate selection operation includes an operation to select candidate equipment from among different choices depending on the mode selected by the mode selection operation. For example, assuming that a chair cannot be fixed to the floor, the chair is not excluded from the equipment list when the second mode is selected in step S2A, but the chair may be excluded from the equipment list 45 when the first mode is selected in step S2A. Alternatively, assuming that a table with legs that cannot be fixed to the floor and a folding table that can be mounted on a wall can be selected as a table, the table with legs is not excluded from the equipment list 45 when the second mode is selected in step S2A, but the table with legs may be excluded from the equipment list 45 when the first mode is selected in step S2A.

Instead of having different choices depending on the mode selected by the mode selection operation, in a case in which the candidate equipment selected in step S6 is equipment that is prohibited to be used in the mode selected in the mode selection operation, it may be determined in step S7 not to allow installation of the candidate equipment at the candidate location. An alert such as “Not available while moving” may be displayed on the equipment layout screen 43.

The processes in steps S7 to S9 are the same as the processes in steps S7 to S9 of FIG. 2, respectively, and thus descriptions thereof are omitted.

The various screens displayed in the present embodiment may be zoomed in by pinching out and zoomed out by pinching in. A design theme such as a vehicle wrapping design may be selected. Various sketching functions may be added, such as the ability to add a trademark to an exterior of the vehicle, or to make a picture drawn on a screen three-dimensional. A realistic mode that displays an actual vehicle in a background may be selected.

The present disclosure is not limited to the embodiment described above. For example, two or more blocks described in the block diagrams may be integrated, or a block may be divided. Instead of executing two or more steps described in the flowcharts in chronological order in accordance with the description, the steps may be executed in parallel or in a different order according to the processing capability of the apparatus that executes each step, or as required. Other modifications can be made without departing from the spirit of the present disclosure.

1. A non-transitory computer readable medium storing a program configured to cause a computer to execute operations, the operations comprising:
displaying, on a display, an image of an equipment layout in a virtual space corresponding to an interior space of a vehicle;
upon accepting a candidate selection operation to select equipment to be used for providing a service in the interior space as candidate equipment and a location in the interior space as a candidate location, determining, with reference to vehicle data defining a specification of the vehicle, whether to allow installation of the candidate equipment at the candidate location; and
upon determining to allow installation of the candidate equipment at the candidate location, updating the equipment layout by arranging a model corresponding to the candidate equipment at a location corresponding to the candidate location in the virtual space.

2. The non-transitory computer readable medium according to claim 1, wherein
the operations further comprise accepting a mode selection operation to select a mode from among a plurality of modes including a first mode of providing the service while the vehicle is moving and a second mode of providing the service while the vehicle is stopped, and
the candidate selection operation includes an operation to select the candidate equipment from among different choices depending on the mode selected by the mode selection operation.

3. The non-transitory computer readable medium according to claim 1, wherein
the vehicle data includes data defining an upper limit of a load or power consumption of the vehicle, and
the determining includes determining whether to allow installation of the candidate equipment at the candidate location, depending on whether a sum of weight or power consumption of the candidate equipment and equipment corresponding to a model having already been arranged in the virtual space exceeds the upper limit.

4. The non-transitory computer readable medium according to claim 1, wherein the operations further comprise:
accepting a service selection operation to select a type of the service; and
setting up the equipment layout by arranging, in the virtual space, a set of models corresponding to a different set of equipment depending on the type selected by the service selection operation.

5. The non-transitory computer readable medium according to claim 1, wherein the displaying includes adjusting a display area or display orientation of the equipment layout according to a change in position or orientation of the display.
